(19) United States
(12) Patent Application Publication
(10) Pub. No.: US 2024/0324192 A1
(43) Pub. Date: Sep. 26, 2024

(54) ONE-TIME PROGRAMMABLE MEMORY DEVICE

(71) Applicant: SAMSUNG ELECTRONICS CO., LTD., Suwon-si (KR)

(72) Inventors: Eun Young LEE, Suwon-si (KR); Shigenobu MAEDA, Suwon-si (KR); Kwan Young KIM, Suwon-si (KR); Bora KIM, Suwon-si (KR); Hoonjin BANG, Suwon-si (KR); Sangjin LEE, Suwon-si (KR)

(21) Appl. No.: 18/613,868

(22) Filed: Mar. 22, 2024

(30) Foreign Application Priority Data
Mar. 24, 2023 (KR) 10-2023-0039246
Apr. 14, 2023 (KR) 10-2023-0049577

(51) Int. Cl. H10B 20/25

(52) U.S. Cl. CPC H10B 20/25

(57) ABSTRACT

A one-time programmable (OTP) memory device includes: a semiconductor substrate having a write region and a read region; write gates disposed in the write region of the semiconductor substrate; read gates disposed in the read region of the semiconductor substrate; source/drain regions arranged adjacent to the write gates and the read gates and arranged in the semiconductor substrate; and a device isolation layer located between the write gates and arranged in the semiconductor substrate, wherein, in the semiconductor substrate, channel regions located below the write gates have a first conductivity type, wherein the source/drain regions have a second conductivity type, different from the first conductivity type, and wherein a pocket well is formed in the write region of the semiconductor substrate and has the second conductivity type.

### CROSS-REFERENCE TO RELATED APPLICATION

This application claims priority under 35 USC § 119 to Korean Patent Application Nos. 10-2023-0039246, filed on Mar. 24, 2023, and 10-2023-0049577, filed on Apr. 14, 2023, in the Korean Intellectual Property Office, the disclosures of which are incorporated by reference herein in their entireties.

### TECHNICAL FIELD

The present inventive concept relates to memory devices, and more particularly, to memory devices having one-time programmable (OTP) memory cells.

### DISCUSSION OF THE RELATED ART

OTP memory devices, including read-only memory cells that may be programmed by manufacturers rather than users, have been used in, for example, display devices, mobile phones, video game consoles, radio-frequency identification (RFID), implantable medical devices, high definition multimedia interfaces (HDMIs), and numerous electronic products. As the use of such OTP memory devices has increased, it has become increasingly desirable to develop technology for intra-chip distribution of electrical characteristics and production yield.

### SUMMARY

According to an embodiment of the present inventive concept, a one-time programmable (OTP) memory device includes: a semiconductor substrate having a write region and a read region; write gates disposed in the write region of the semiconductor substrate; read gates disposed in the read region of the semiconductor substrate; source/drain regions arranged adjacent to the write gates and the read gates and arranged in the semiconductor substrate; and a device isolation layer located between the write gates and arranged in the semiconductor substrate, wherein, in the semiconductor substrate, channel regions located below the write gates have a first conductivity type, wherein the source/drain regions have a second conductivity type, different from the first conductivity type, and wherein a pocket well is formed in the write region of the semiconductor substrate and has the second conductivity type.

According to an embodiment of the present inventive concept, a one-time programmable (OTP) memory device includes: a semiconductor substrate including a main cell array and a redundant cell array, wherein the main cell array and the redundant cell array each have a write region and a read region; write gates disposed in the write region of the semiconductor substrate; read gates disposed in the read region of the semiconductor substrate; source/drain regions arranged adjacent to the write gates and the read gates in the semiconductor substrate; a bit line connected to the source/drain regions that are located between the read gates; a device isolation layer located between the write gates in the semiconductor substrate; first word line connection lines connecting the write gates to the read gates in the main cell array and extending in a first direction; and second word line connection lines connecting the write gates to the read gates in the redundant cell array, and extending in the first direction, wherein the second word line connection lines are located in a corresponding region between the first word line connection lines, wherein channel regions are located below the write gates and the read gates and have a first conductivity type, wherein the source/drain regions have a second conductivity type, different from the first conductivity type, and wherein a pocket well having the second conductivity type is formed below the channel regions of the write gates.

According to an embodiment of the present inventive concept, a one-time programmable (OTP) memory device includes: a semiconductor substrate including a main cell array and a redundant cell array, wherein the main cell array and the redundant cell array each have cell regions defined by device isolation layers; a write region and a read region located in each of the cell regions; a pair of write gates located in the write region of the cell region; a pair of read gates arranged in the read region of the cell region and located between the pair of write gates; source/drain regions disposed adjacent to the pair of write gates and the pair of read gates and disposed in the semiconductor substrate; a bit line connected to the source/drain regions that are located between the pair of read gates on the semiconductor substrate; first word line connection lines connecting the write gates to the read gates of the cell regions and extending in a first direction in the main cell array; second word line connection lines connecting the write gates to the read gates of the cell regions, and extending in the first direction; and dummy cells arranged on both sides of each of the first word line connection lines and the second word line connection lines, wherein channel regions are located below each of the pair of write gates and the pair of read gates and have a first conductivity type, wherein the source/drain regions have a second conductivity type, different from the first conductivity type, and wherein a pocket well is disposed below the channel region of each of the pair of write gates and has the second conductivity type.

### BRIEF DESCRIPTION OF THE DRAWINGS

The above and other aspects of the present inventive concept will become more apparent by describing in detail embodiments thereof, with reference to the accompanying drawings, in which:

FIG. 1 is a perspective view illustrating a display device including a one-time programmable (OTP) memory device according to an embodiment of the present inventive concept;

FIG. 2 is a layout illustrating a memory cell array of an OTP memory device according to an embodiment of the present inventive concept;

FIG. 3 is a cross-sectional view taken along line X-X′ of FIG. 2;

FIG. 4 is a layout illustrating a memory cell array of an OTP memory device according to an embodiment of the present inventive concept;

FIG. 5 is a schematic diagram illustrating defects of a unit cell corresponding to FIG. 4;

FIG. 6 is a layout illustrating a memory cell array of an OTP memory device according to an embodiment of the present inventive concept;

FIG. 7 is an enlarged view of portion AA of FIG. 6;

FIG. 8 is an enlarged view of portion BB of FIG. 6;

FIG. 9 is a layout illustrating a memory cell array of an OTP memory device according to an embodiment of the present inventive concept;

FIG. 10 is a flowchart illustrating a method of operating a program for an OTP memory device, according to an embodiment of the present inventive concept; and

FIG. 11 is a diagram illustrating a system including an OTP memory device according to an embodiment of the present inventive concept.

### DETAILED DESCRIPTION OF THE EMBODIMENTS

Hereinafter, embodiments of the present inventive concept are described in detail with reference to the accompanying drawings.

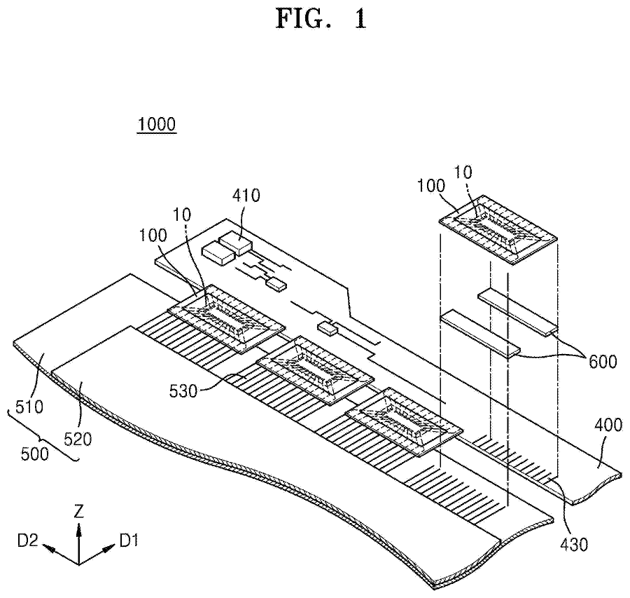

FIG. 1 is a perspective view illustrating a display device 1000 including a one-time programmable (OTP) memory device according to an embodiment of the present inventive concept.

Referring to FIG. 1, the display device 1000 may include at least one chip-on-film (COF) package 100, a driving printed circuit board (PCB) 400, and a display panel 500.

The COF package 100 may be a package including an OTP memory device 10 that is a display driver IC (DDI). In some embodiments of the present inventive concept, one OTP memory device 10 may be located in one COF package 100. In some embodiments of the present inventive concept, different types of OTP memory devices 10 may also be located in one COF package 100. For example, the OTP memory device 10 may include a source driving chip and/or a gate driving chip.

The COF package 100 may be located between the driving PCB 400 and the display panel 500 and connected to the driving PCB 400 and the display panel 500. The COF package 100 may receive a signal output from the driving PCB 400 and transmit the signal to the display panel 500.

One or more driving circuit chips 410 capable of simultaneously or sequentially applying power and signals to the COF package 100 may be mounted on the driving PCB 400.

The display panel 500 may be, for example, a liquid crystal display (LCD) panel, a light emitting diode (LED) panel, an organic LED (OLED) panel, a plasma display panel (PDP), or the like.

The COF package 100 may be electrically connected to each of a driving connection wiring 430 of the driving PCB 400 and a panel connection wiring 530 of the display panel 500.

In some embodiments of the present inventive concept, one COF package 100 may be connected between the driving PCB 400 and the display panel 500. For example, when the display panel 500 is intended to provide a screen of a small area, such as a mobile phone, or the display panel 500 supports a relatively low resolution, the display device 1000 may include a single COF package 100.

In some embodiments of the present inventive concept, a plurality of COF packages 100 may be connected between the driving PCB 400 and the display panel 500. For example, if the display panel 500 is to provide a large-area screen like a television or the display panel 500 supports a relatively high resolution, the display device 1000 may include a plurality of COF packages 100.

The COF package 100 may be connected to one side of the display panel 500. However, the present inventive concept is not limited thereto, and in some embodiments of the present inventive concept, one or a plurality of the COF packages 100 may be connected to each of two or more sides of the display panel 500.

The display panel 500 may include a transparent substrate 510, an image region 520 formed on the transparent substrate 510, and a panel connection wiring 530. The transparent substrate 510 may be, for example, a glass substrate or a flexible substrate. A plurality of pixels of the image region 520 may be connected to a plurality of corresponding panel connection wirings 530 and may operate according to a signal provided by the OTP memory device 10 that is mounted on the COF package 100.

The COF package 100 may have an input pad formed at one end thereof and an output pad formed at the other end thereof. The input pad and the output pad may be respectively connected to the driving connection wiring 430 of the driving PCB 400 and the panel connection wiring 530 of the display panel 500 through anisotropic conductive layers 600.

The anisotropic conductive layer 600 may be, for example, an anisotropic conductive film or an anisotropic conductive paste. The anisotropic conductive layer 600 may have a structure in which conductive particles may be dispersed in an insulating adhesive layer. In addition, the anisotropic conductive layer 600 may have anisotropic electrical characteristics such that the anisotropic conductive layer 600 is conducted in an electrode direction (e.g., a Z direction) when connected and insulated from neighboring electrodes in a direction (e.g., a D1 direction) between the electrodes. When an adhesive melts to the anisotropic conductive layer 600 by applying heat and pressure thereto, the conductive particles may be arranged and electrically conducted between opposing electrodes, for example, between the input pad and the driving connection wiring 430 and between the output pad and the panel connection wiring 530, while the adhesive may fill a space between adjacent electrodes to insulate therebetween.

Hereinafter, the OTP memory element 10 included in the display device 1000 according to an embodiment of the present inventive concept is described in detail.

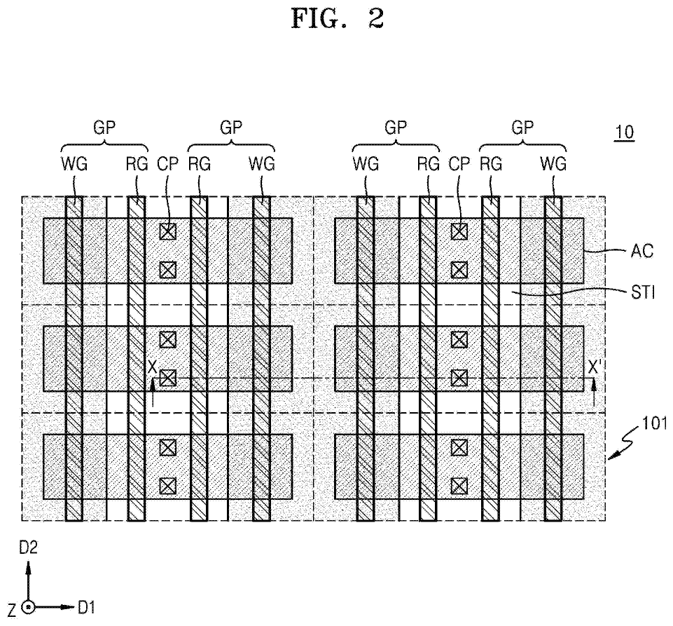

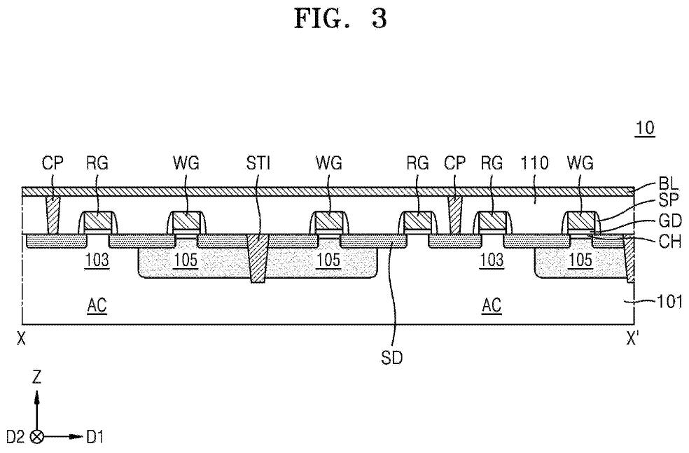

FIG. 2 is a layout illustrating a memory cell array of the OTP memory device 10 according to an embodiment of the present inventive concept, and FIG. 3 is a cross-sectional view taken along line X-X′ of FIG. 2.

Referring to FIGS. 2 and 3 together, the cell array of the OTP memory device 10 according to an embodiment of the present inventive concept may include a plurality of gate patterns GP that are provided on the semiconductor substrate 101.

The semiconductor substrate 101 may include active regions AC defined by device isolation layers STI. The active regions AC may extend parallel to each other and may be formed in a line shape, a bar shape, or a polygonal shape. Bit lines BL may be respectively formed on the active regions AC. For example, each of the bit lines BL may overlap a corresponding one of the active regions AC in a plan view.

The semiconductor substrate 101 may be, for example, a silicon (Si) wafer and may include, for example, single-crystal silicon, polycrystalline silicon, and/or amorphous silicon. However, the material of the semiconductor substrate 101 is not limited to silicon (Si). In some embodiments of the present inventive concept, the semiconductor substrate 101 may include group IV semiconductors, such as germanium (Ge), group IV compound semiconductors, such as silicon germanium (SiGe) or silicon carbide (SiC), or group III-V compound semiconductors, such as gallium arsenide (GaAs), indium arsenide (InAs), or indium phosphide (InP).

The bit lines BL may include at least one of conductive materials. For example, the bit lines BL may include at least one of aluminum, tungsten, copper, titanium nitride, tantalum nitride, tungsten nitride, and/or doped silicon, but the present inventive concept is not limited thereto.

The cell array may include a plurality of gate patterns GP provided between the semiconductor substrate 101 and the bit lines BL. The gate patterns GP may cross the bit lines BL and the active regions AC. The gate patterns GP may include write gates WG, which constitute write gate couples, and read gates RG, which constitute read gate couples. Each of the write gate couples may include two adjacent gate patterns GP, among the gate patterns GP, and each of the read gate couples may also include other two adjacent gate patterns GP, among the gate patterns GP. In addition, each of the gate patterns GP may be used as one of the write and read gates WG and RG.

The read gate couples and the write gate couples may be alternately arranged in an extension direction of the bit lines BL. In other words, a pair of write gates WG constituting one write gate couple may be located between two adjacent read gate couples, and a pair of read gates RG constituting one read gate couple may be located between two adjacent write gate couples.

The gate patterns GP may be formed using the same manufacturing process. Accordingly, the write and read gates WG and RG may include substantially the same material, thickness, and shape as each other. For example, the write and read gates WG and RG may include a conductive material having a certain work function and contribute to adjusting a threshold voltage Vth of the active region AC located therebelow.

In some embodiments of the present inventive concept, each of the write and read gates WG and RG may include at least one of metal nitrides and metals. For example, each of the write and read gates WG and RG may include a first metal material layer and a second metal material layer, which are sequentially stacked on each other and include different materials from each other. The first metal material layer may include metal nitride, for example, titanium nitride (TiN), tantalum nitride (TaN), titanium aluminum nitride (TiAlN), tantalum aluminum nitride (TaAlN), niobium nitride (NbN), vanadium nitride (VN), and/or tungsten nitride (WN). The second metal material layer may include materials having a specific resistance that is lower than that of the first metal material layer, for example, aluminum or tungsten.

In some embodiments of the present inventive concept, when the OTP memory device 10 has a CMOS structure, the forming of the gate patterns GP may include forming a gate electrode of an nMOSFET and forming a gate electrode of a pMOSFET independently of the forming of the gate patterns GP. However, the embodiments of the present inventive concept are not limited to the independently forming of the gate electrodes of the nMOSFET and pMOSFET.

The cell array may further include gate insulating layers GD that is located between the gate patterns GP and the active regions AC. For example, each of the gate patterns GP may face the active regions AC with the gate insulating layers GD disposed therebetween. The gate insulating layers GD may include at least one of high dielectric layers. The gate insulating layers GD disposed below the write gates WG may be substantially the same as the gate insulating layers GD disposed below the read gates RG with regard to material, thickness, and shape.

In some embodiments of the present inventive concept, the gate insulating layers GD may include at least one of hafnium oxide, hafnium silicate, zirconium oxide, and/or zirconium silicate, but the present inventive concept is not limited to these materials. The gate insulating layers GD may be formed using any one of, for example, chemical vapor deposition (CVD), atomic layer deposition (ALD), atomic beam epitaxy (MBE), pulsed laser deposition (PLD), and liquid source misted chemical deposition (LSMCD).

The cell array may further include a plurality of source/drain regions SD located between the gate patterns GP. For example, the source/drain regions SD may be located between the read gates RG constituting the read gate couples, between the write gates WG constituting the write gate couples, and between the write and read gate couples.

The source/drain regions SD may be located in the active regions AC that are inside the semiconductor substrate 101. Each of the active regions AC overlaps with the source/drain regions SD, and the source/drain regions SD provided in any one of the active regions AC are spaced apart from the source/drain regions SD that are provided in the other of the active regions AC. Each of the source/drain regions SD may be formed using a doping process. According to the present embodiment, the source/drain regions SD may be formed to have an n-type conductivity.

Each of the bit lines BL may be electrically connected to a corresponding one of the source/drain regions SD through a plurality of contact plugs CP. The contact plugs CP may be located between the read gates RG constituting the read gate couples, and the contact plugs CP may be respectively connected to the source/drain regions SD that are located between the read gates RG constituting the read gate couples. A silicide pattern may be formed between the contact plugs CP and the source/drain regions SD.

Gate spacers SP may be provided on both sidewalls of each of the gate patterns GP. The gate spacers SP may be formed after forming the gate patterns GP, and each of the gate spacers SP may have a width that decreases in a direction away from the semiconductor substrate 101. The gate spacers SP may include, for example, at least one of a silicon oxide layer, a silicon oxynitride layer, and/or a silicon nitride layer.

In addition, an interlayer insulating layer 110 may be provided between the bit lines BL and the gate patterns GP. The interlayer insulating layer 110 may structurally support the bit lines BL and enable electrical separation between the bit lines BL and the gate patterns GP. The interlayer insulating layer 110 may include, for example, at least one of a silicon oxide layer, a silicon oxynitride layer, a silicon nitride layer, and a low-k dielectric layer. The contact plugs CP may pass through the interlayer insulating layer 110 and be respectively connected to the source/drain regions SD.

A substrate well 103 and a pocket well 105 may be formed in the semiconductor substrate 101. As described above, when the source/drain regions SD are formed to have an n-type conductivity, the substrate well 103 has a conductivity (i.e., p type) opposite to that of the source/drain regions SD when formed in the semiconductor substrate 101. In the OTP memory device 10 according to an embodiment of the present inventive concept, the pocket well 105 may be formed below the write gates WG, while having the same conductivity type (i.e., n-type) as that of the source/drain regions SD.

In a plan view, the pocket well 105 may be formed to cross the bit lines BL. For example, the pocket well 105 may be formed to at least partially overlap the write gates WG constituting the write gate couples and the source/drain regions SD located between the pocket well 105 and the write gates WG.

In the OTP memory device 10 according to an embodiment of the present inventive concept, a vertical level of a bottom surface of the device isolation layer STI may be lower than a vertical level of a bottom surface of the pocket well 105. Here, one sidewall of the pocket well 105 may contact the device isolation layer STI, and the other sidewall of the pocket well 105 may contact the semiconductor substrate 101. In addition, the pocket well 105 may be disposed to contact the channel regions CH of the write gates WG and the source/drain regions SD.

In addition, in the OTP memory device 10 according to an embodiment of the present inventive concept, channel regions CH having a conductivity type (e.g., p type) opposite to that of the source/drain regions SD may be disposed below the write and read gates WG and RG. For example, the channel regions CH may be disposed immediately below the write and read gates WG and RG.

Typically, the OTP memory device 10, including read-only memory cells that may be programmed by manufacturers rather than users, have been used in, for example, display devices, mobile phones, video game consoles, RFID, and implantable medical devices, high definition multimedia interfaces (HDMIs), and numerous electronic products. As the use of the OTP memory device 10 has increased, it has become increasingly desirable to develop technology for intra-chip distribution of electrical characteristics and production yield.

In the OTP memory device 10 according to an embodiment of the present inventive concept, the pocket well 105 disposed below the write gates WG may be formed to have a conductivity type that is the same as that of the source/drain regions SD, while having a conductivity type opposite to that of the channel regions CH. Accordingly, the write gate WG, the pocket well 105, and the source/drain regions SD operate, while forming a new current path. This configuration may effectively block a current path of a well leakage current between the write gates WG and the active region AC located therebelow. Accordingly, the program current may have good characteristics in the write gates WG.

In addition, the OTP memory device 10 according to an embodiment of the present inventive concept may prevent deterioration of program characteristics by reducing intra-chip distribution of electrical characteristics and satisfy high production yield by suppressing the occurrence of fail cells.

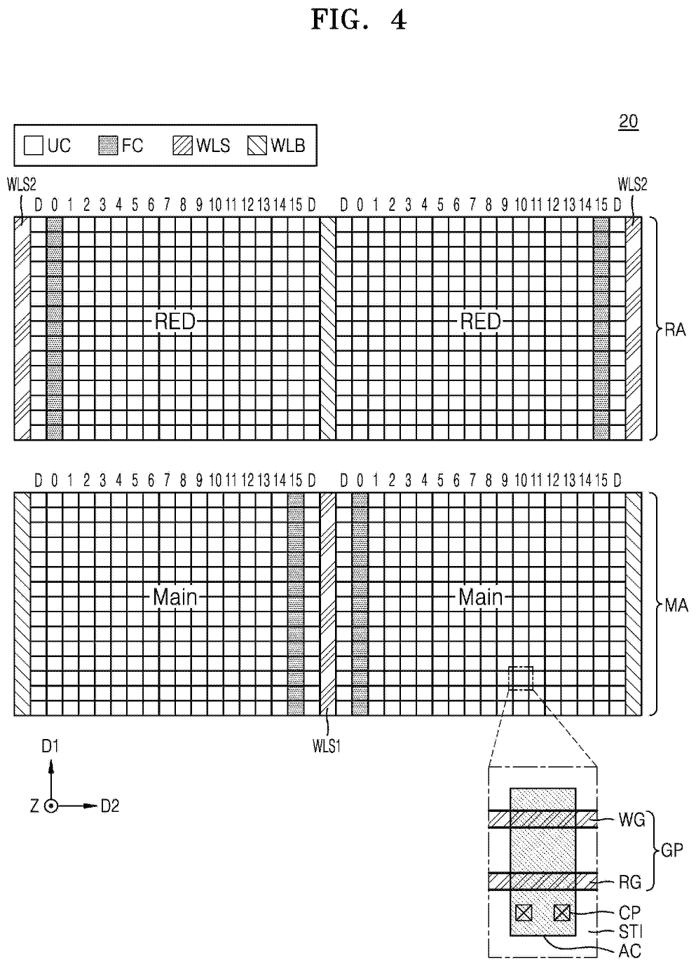

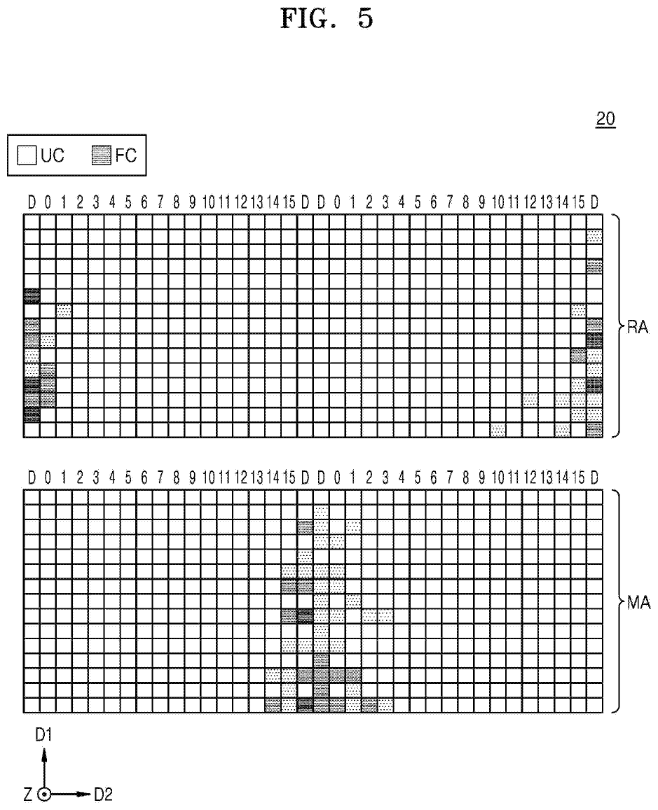

FIG. 4 is a layout illustrating a memory cell array of an OTP memory device 20 according to an embodiment of the present inventive concept, and FIG. 5 is a schematic diagram illustrating defects of a unit cell corresponding to FIG. 4.

Referring to FIGS. 4 and 5 together, the OTP memory device 20 according to an embodiment of the present inventive concept may include a main cell array MA and a redundant cell array RA.

A plurality of unit cells UC may be arranged in the first direction D1 and the second direction D2 in the main cell array MA. As described above for the OTP memory device 10, each of the unit cells UC may be disposed such that gate patterns GP cross active regions AC. The gate patterns GP may include write gates WG and read gates RG. In addition, the gate patterns GP may be designed to share contact plugs CP with neighboring unit cells UC.

First word line connection lines WLS1 connecting the write gates WG to the read gates RG and extending in the first direction D1 may be located in the main cell array MA. In addition, second word line connection lines WLS2 connecting the write gates WG to the read gates RG and extending in the first direction D1 may be located in the redundant cell array RA.

Here, the first word line connection lines WLS1 and the second word line connection lines WLS2 might not be located in a straight line in the first direction D1. In other words, the first word line connection lines WLS1 and the second word line connection lines WLS2 may be arranged in a zigzag pattern or alternating pattern.

For example, the second word line connection lines WLS2 might not be formed in a region of the redundant cell array RA corresponding to the first word line connection lines WLS1, or the second word line connection lines WLS2 may be formed but a word line blank WLB in which a contact plug is not disposed may be located. In addition, the first word line connection lines WLS1 might not be formed in a region of the main cell array MA corresponding to the second word line connection lines WLS2, or the first word line connection lines WLS1 may be formed but a word line blank WLB in which a contact plug is not disposed may be located.

Accordingly, in the main cell array MA, in the second direction D2 substantially perpendicular to the first direction D1, 2N (here, N is a positive integer) unit cells UC may be located between the first word connection lines WLS1 facing each other, and N unit cells UC may be located between the first word line connection line WLS1 and the word line blank WLB adjacent to each other.

In addition, in the redundant cell array RA, in the second direction D2, 2N unit cells UC may be located between the second word line connection lines WLS2 facing each other, and N unit cells UC may be located between the second word line connection lines WLS2 and the word line blank WLB adjacent to each other.

In general, in the OTP memory device 20, the main cell array MA and the redundant cell array RA may include the same number of unit cells UC as each other. In the OTP memory device 20, to determine whether the unit cells UC are pass or fail cells, a method of summing cell currents generated through the same bit line BL of the main cell array MA and the redundant cell array RA is used. In most cases, fail cells FC may occur around a region in which the word line connection line WLS is disposed. Accordingly, although dummy cells are arranged on both sides of the word line connection line WLS, the occurrence of fail cells FC is not completely addressed.

As a solution, in the OTP memory device 20 according to an embodiment of the present inventive concept, the first word line connection lines WLS1, which is located in the main cell array MA, and the second word line connection lines WLS2, which is located in the redundant cell array RA, may be arranged in a zigzag pattern, thereby reducing the occurrence of fail cells FC.

For example, in the OTP memory device 20 according to an embodiment of the present inventive concept, a fail cell is determined by summing the cell currents generated through the same bit line BL of the main cell array MA and the redundant cell array RA, and thus, the possibility that fail cells FC occur due to current summation with pass cells in the vicinity of the word line blank WLB may be reduced.

As shown in FIG. 5, according to experimental results of the inventors, it can be seen that the expected results coincide with the experimental results to a large extent. For example, in the drawing, a darker hatched portion represents a higher defect rate. As such, in the OTP memory device 20 according to an embodiment of the present inventive concept, because the regions in which the fail cells FC of the main cell array MA and the redundant cell array RA are distributed do not overlap each other, the possibility that a fail cell FC occurs may be reduced.

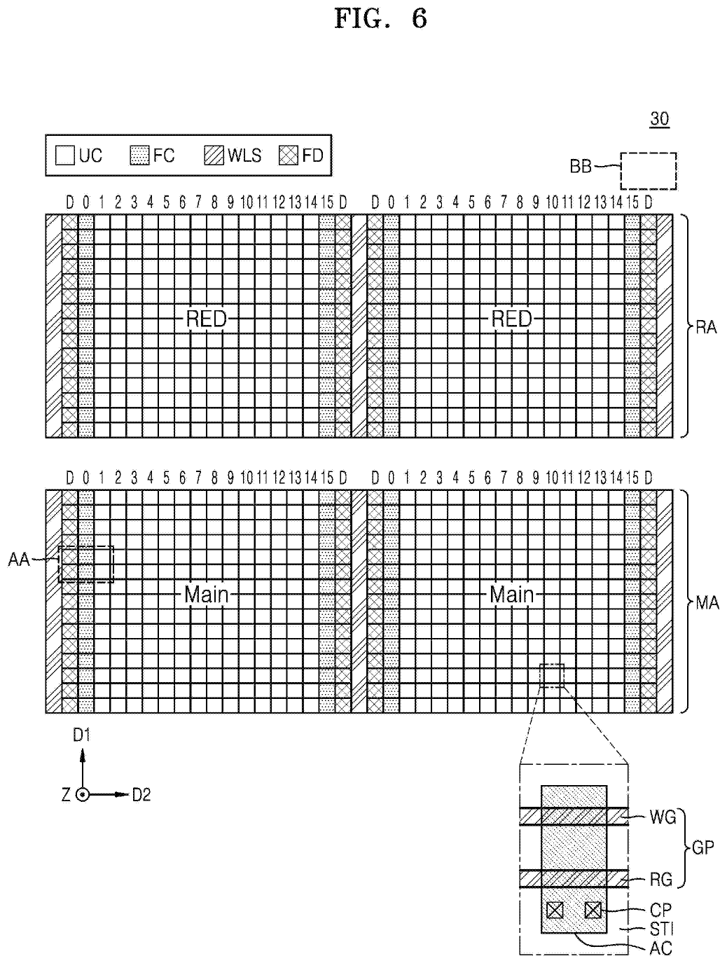

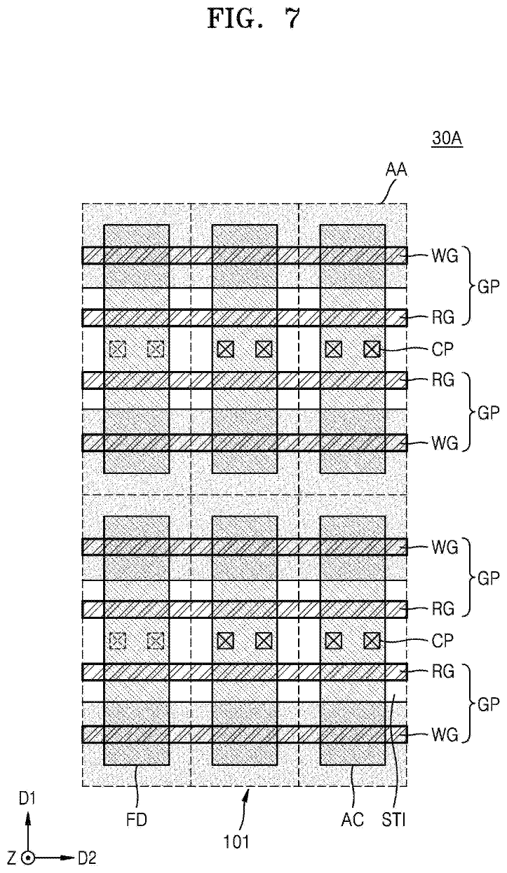

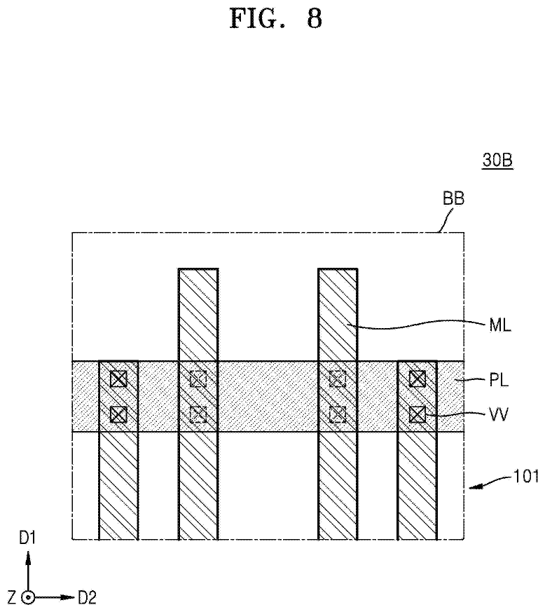

FIG. 6 is a layout illustrating a memory cell array of an OTP memory device 30 according to an embodiment of the present inventive concept. FIG. 7 is an enlarged view of portion AA of FIG. 6, and FIG. 8 is an enlarged view of portion BB of FIG. 6.

Referring to FIGS. 6 to 8 together, the OTP memory device 30 according to an embodiment of the present inventive concept may include a main cell array MA and a redundant cell array RA.

The main cell array MA may include a plurality of unit cells UC. As in the OTP memory device 10 described above, each of the unit cells UC may be disposed such that gate patterns GP cross active regions AC. The gate patterns GP may include write gates WG and read gates RG. In addition, the gate patterns GP may be designed to share contact plugs CP with neighboring unit cells UC.

In the main cell array MA and the redundant cell array RA, word line connection lines WLS connecting the write gates WG to the read gates RG to each other and extending in the first direction D1 may be located.

Here, the word line connection lines WLS may be arranged in a straight line in the first direction D1. In other words, the word line connection lines WLS may be arranged in a straight line shape connecting the main cell array MA and the redundant cell array RA to each other.

In the OTP memory device 30 according to an embodiment of the present inventive concept, dummy cells FD may be arranged on both sides of each of the word line connection lines WLS, and the dummy cells FD may be in a floating state.

In general, the dummy cells may be substantially the same as the unit cells UC with regard to material, thickness, and shape. However, the dummy cells do not perform read/write functions. As such, the dummy cells do not actually operate but may be still electrically connected to a power line PL to be used as a path inducing a degradation of gate potential in the event of a gate-to-well breakdown.

To solve this, an OTP memory device 30A according to an embodiment of the present inventive concept may be designed such that a wiring line ML is disposed above the dummy cells FD and connected to the power line PL, but the contact plugs CP connecting the dummy cells FD to the wiring line ML are omitted, as a method of forming the dummy cells FD in a floating state. The contact plugs CP indicated by the dashed line in the drawing indicate that they are omitted.

In addition, an OTP memory device 30B according to an embodiment of the present inventive concept may be designed such that a wiring line ML is disposed above the dummy cells FD, and contact plugs CP connecting the dummy cells FD to the wiring line ML may be provided, but vertical vias VV connecting the wiring line ML to the power line PL may be omitted. The vertical vias VV indicated by the dashed line in the drawing indicate that they are omitted.

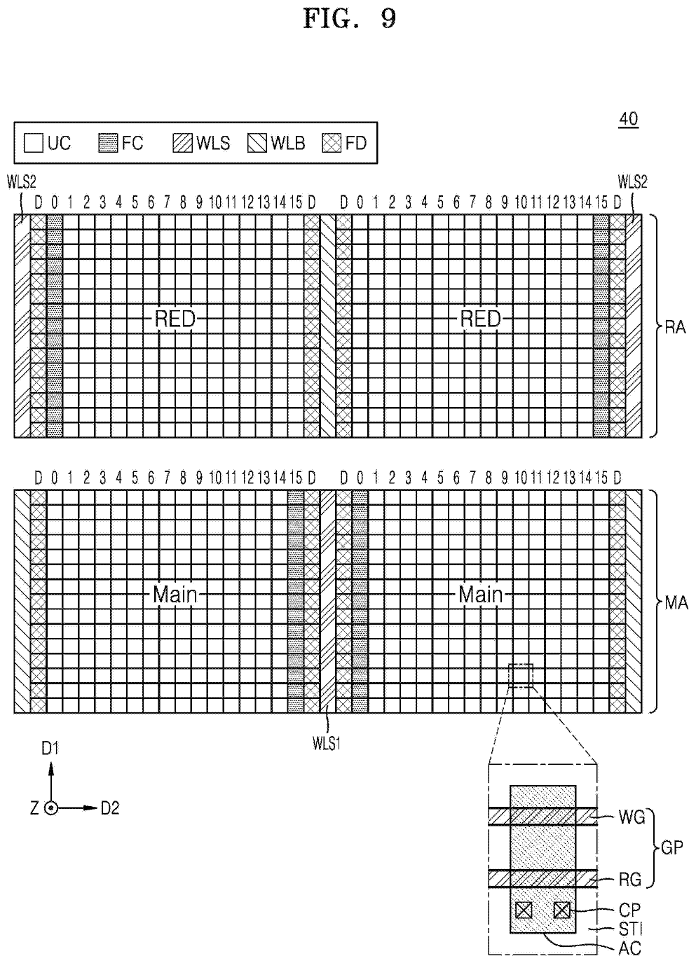

FIG. 9 is a layout illustrating a memory cell array of an OTP memory device 40 according to an embodiment of the present inventive concept.

Referring to FIG. 9, the OTP memory device 40 according to an embodiment of the present inventive concept may include a main cell array MA and a redundant cell array RA.

The main cell array MA may include a plurality of unit cells UC. As in the OTP memory device 10 described above, each of the unit cells UC may be disposed such that gate patterns GP cross active regions AC. The gate patterns GP may include write gates WG and read gates RG. In addition, the gate patterns GP may be designed to share contact plugs CP with neighboring unit cells UC.

First word line connection lines WLS1 connecting the write gates WG to the read gates RG and extending in the first direction D1 may be located in the main cell array MA. In addition, second word line connection lines WLS2 connecting the write gates WG to the read gates RG and extending in the first direction D1 may be located in the redundant cell array RA.

Here, the first word line connection lines WLS1 and the second word line connection lines WLS2 might not be located in a straight line in the first direction D1. In other words, the first word line connection lines WLS1 and the second word line connection lines WLS2 may be arranged in a zigzag pattern or an alternating pattern.

For example, the second word line connection lines WLS2 might not be formed in a region of the redundant cell array RA corresponding to the first word line connection lines WLS1, or the second word line connection lines WLS2 may be formed but a word line blank WLB in which a contact plug is not disposed may be located. In addition, the first word line connection lines WLS1 might not be formed in a region of the main cell array MA corresponding to the second word line connection lines WLS2, or the first word line connection lines WLS1 may be formed but a word line blank WLB in which a contact plug is not disposed may be located.

In addition, dummy cells FD may be arranged on both sides of each of the first word line connection lines WLS1 and the second word line connection lines WLS2, and the dummy cells FD may be in a floating state. As a method of forming the dummy cells FD in a floating state, contact plugs CP connecting the dummy cells FD to the wiring line ML may be omitted, or vertical vias VV connecting the wiring line ML to the power line PL may be omitted.

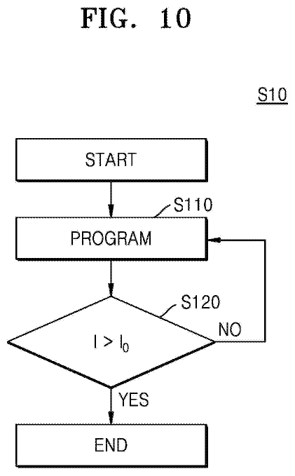

FIG. 10 is a flowchart illustrating a method of operating a program for an OTP memory device, according to an embodiment of the present inventive concept.

Referring to FIG. 10, a program operation for an OTP memory device (S10) includes executing the program operation (S110) and determining whether the program operation is effectively executed (S120).

Due to intra-chip program distribution, some of memory cells constituting the OTP memory device might not have intended program characteristics. For example, a program current in some programmed cells may be less than desired.

To solve the problem of such incomplete programming, the program operation may be additionally performed on incompletely programmed cells. However, this additional program operation is performed on a memory cell having resistance reduced by an initial program operation. Accordingly, during the additional program operation, the amount of current passing through the corresponding memory cell may excessively increase, compared to a case in which the memory cell is not programmed.

Such excessive current may cause technical problems, such as the occurrence of excessive Joule-heat in the corresponding memory cell and consequent disconnection of a path. As a result, as the additional program operation is repeated, a read current of the memory cell may decrease opposite to what was intended.

However, the OTP memory devices 10, 20, 30, and 40 according to an embodiment of the present inventive concept described above may effectively solve these technical problems. For example, the OTP memory devices 10, 20, 30, and 40 according to an embodiment of the present inventive concept may prevent deterioration of program characteristics by reducing intra-chip distribution of electrical characteristics, and may satisfy high production yield by suppressing the occurrence of fail cells.

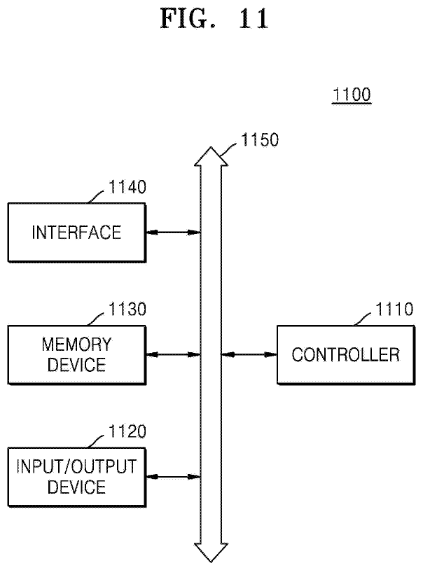

FIG. 11 is a configuration diagram illustrating a system 1100 including an OTP memory device according to an embodiment of the present inventive concept.

Referring to FIG. 11, the system 1100 includes a controller 1110, an input/output device 1120, a memory device 1130, an interface 1140, and a bus 1150.

The system 1100 may be a mobile system or a system that transmits or receives information. In some embodiments of the present inventive concept, the mobile system may be a portable phone, portable computer, web tablet, digital music player, or memory card.

The controller 1110 may control an execution program in the system 1100 and may include, for example, a microprocessor, a digital signal processor, a microcontroller, or a device similar thereto.

The input/output device 1120 may be used to input or output data from the system 1100. The system 1100 may be connected to an external device, for example, a personal computer or a network, using the input/output device 1120 and exchange data with the external device. The input/output device 1120 may be, for example, a touch screen, a touch pad, a keyboard, or a display device.

The memory device 1130 may be used to store instructions that are executed by controller 1110. The memory device 1130 may include any one of the OTP memory devices 10, 20, 30, and 40 according to an embodiment of the present inventive concept described above.

The interface 1140 may be a data transmission path between the system 1100 and an external device. The controller 1110, the input/output device 1120, the memory device 1130, and the interface 1140 may communicate with each other via the bus 1150.

While the present inventive concept has been particularly shown and described with reference to example embodiments thereof, it will be apparent to those of ordinary skill in the art that various changes in form and detail may be made thereto without departing from the spirit and scope of the present inventive concept.

What is claimed is:

1. A one-time programmable (OTP) memory device comprising:
a semiconductor substrate having a write region and a read region;
write gates disposed in the write region of the semiconductor substrate;
read gates disposed in the read region of the semiconductor substrate;
source/drain regions arranged adjacent to the write gates and the read gates and arranged in the semiconductor substrate; and
a device isolation layer located between the write gates and arranged in the semiconductor substrate,
wherein, in the semiconductor substrate, channel regions located below the write gates have a first conductivity type,
wherein the source/drain regions have a second conductivity type, different from the first conductivity type, and
wherein a pocket well is formed in the write region of the semiconductor substrate and has the second conductivity type.

2. The OTP memory device of claim 1, wherein
a vertical level of a bottom surface of the device isolation layer is lower than a vertical level of a bottom surface of the pocket well,
wherein a first sidewall of the pocket well is in contact with the device isolation layer, and
wherein a second sidewall of the pocket well is in contact with the semiconductor substrate.

3. The OTP memory device of claim 2, wherein the pocket well is located to contact the channel regions of the write gates and the source/drain regions of the write gates.

4. The OTP memory device of claim 1, wherein
the semiconductor substrate has the first conductivity type,
the first conductivity type is p-type, and the second conductivity type is n-type.

5. The OTP memory device of claim 1, wherein
the semiconductor substrate has a main cell array and a redundant cell array,
wherein first word line connection lines connecting the write gates to the read gates and extending in a first direction are disposed in the main cell array,
wherein second word line connection lines connecting the write gates to the read gates and extending in the first direction are disposed in the redundant cell array, and
wherein each of the first word line connection lines and the second word line connection lines are not disposed in a straight line in the first direction.

6. The OTP memory device of claim 5, wherein
2N main cells are arranged between the first word line connection lines that face each other in a second direction that is substantially perpendicular to the first direction, wherein N is a positive integer, and
N main cells are arranged between the first word line connection line and the second word line connection line adjacent to each other in the second direction.

7. The OTP memory device of claim 6, wherein
2N redundant cells are arranged between the second word line connection lines that face each other in the second direction, and
N redundant cells are arranged between the first word line connection line and the second word line connection line adjacent to each other in the second direction.

8. The OTP memory device of claim 5, wherein
dummy cells are arranged on both sides of each of the first word line connection lines, and
the dummy cells are in a floating state.

9. The OTP memory device of claim 8, wherein
a wiring line is disposed above the dummy cells, and
contact plugs connect the dummy cells to the wiring line, but the wiring line is not connected to a power line.

10. The OTP memory device of claim 8, wherein
a wiring line is disposed above the dummy cells, and
the wiring line is connected to a power line, but contact plugs connecting the dummy cells to the wiring line are not provided.

11. A one-time programmable (OTP) memory device comprising:
a semiconductor substrate including a main cell array and a redundant cell array, wherein the main cell array and the redundant cell array each have a write region and a read region;
write gates disposed in the write region of the semiconductor substrate;
read gates disposed in the read region of the semiconductor substrate;
source/drain regions arranged adjacent to the write gates and the read gates in the semiconductor substrate;
a bit line connected to the source/drain regions that are located between the read gates;
a device isolation layer located between the write gates in the semiconductor substrate;
first word line connection lines connecting the write gates to the read gates in the main cell array and extending in a first direction; and
second word line connection lines connecting the write gates to the read gates in the redundant cell array, and extending in the first direction, wherein the second word line connection lines are located in a corresponding region between the first word line connection lines,
wherein channel regions are located below the write gates and the read gates and have a first conductivity type,
wherein the source/drain regions have a second conductivity type, different from the first conductivity type, and
wherein a pocket well having the second conductivity type is formed below the channel regions of the write gates.

12. The OTP memory device of claim 11, wherein
the pocket well contacts the channel regions of the write gates and the source/drain regions of the write gates, and
the first conductivity type is p-type, and the second conductivity type is n-type.

13. The OTP memory device of claim 11, wherein
2N main cells are arranged between the first word line connection lines that face each other in a second direction that is substantially perpendicular to the first direction, wherein N is a positive integer, and
N main cells are arranged between the first word line connection line and the second word line connection line that are adjacent to each other in the second direction.

14. The OTP memory device of claim 13, wherein
dummy cells are arranged on both sides of each of the first word line connection lines and the second word line connection lines, and
the dummy cells are in a floating state.

15. The OTP memory device of claim 14, wherein the main cells constitute a display driver integrated circuit.

16. A one-time programmable (OTP) memory device comprising:
a semiconductor substrate including a main cell array and a redundant cell array, wherein the main cell array and the redundant cell array each have cell regions defined by device isolation layers;
a write region and a read region located in each of the cell regions;
a pair of write gates located in the write region of the cell region;
a pair of read gates arranged in the read region of the cell region and located between the pair of write gates;
source/drain regions disposed adjacent to the pair of write gates and the pair of read gates and disposed in the semiconductor substrate;
a bit line connected to the source/drain regions that are located between the pair of read gates on the semiconductor substrate;
first word line connection lines connecting the write gates to the read gates of the cell regions and extending in a first direction in the main cell array;
second word line connection lines connecting the write gates to the read gates of the cell regions, and extending in the first direction; and
dummy cells arranged on both sides of each of the first word line connection lines and the second word line connection lines,
wherein channel regions are located below each of the pair of write gates and the pair of read gates and have a first conductivity type,
wherein the source/drain regions have a second conductivity type, different from the first conductivity type, and
wherein a pocket well is disposed below the channel region of each of the pair of write gates and has the second conductivity type.

17. The OTP memory device of claim 16, wherein
a vertical level of a bottom surface of the device isolation layer is lower than a vertical level of a bottom surface of the pocket well,
the semiconductor substrate has the first conductivity type, wherein the first conductivity type is p-type, and the second conductivity type is n-type, and
the dummy cells are in a floating state.

18. The OTP memory device of claim 17, further comprising:
a wiring line disposed above the dummy cells,
wherein contact plugs connect the dummy cells to the wiring line, but the wiring line is not connected to a power line, or
the wiring line is connected to the power line, but contact plugs do not connect the dummy cells to the wiring line.

19. The OTP memory device of claim 16, wherein a number of cell regions included in the main cell array is equal to a number of cell regions included in the redundant cell array.

20. The OTP memory device of claim 19, wherein, in a second direction substantially perpendicular to the first direction, a first interval between the first word line connection lines, which face each other, is substantially equal to a second interval between the second word line connection lines, which face each other.
